(19) United States
(12) Patent Application Publication
(10) Pub. No.: US 2004/0035532 A1
(43) Pub. Date: Feb. 26, 2004

(54) Etching apparatus for use in manufacturing a semiconductor device and shield ring for upper electrode thereof

(76) Inventor: Soon-Jong Jung, Suwon-City (KR)

Correspondence Address: VOLENTINE FRANCOS, P.L.L.C., Suite 150, 12200 Sunrise Valley Drive, Reston, VA, 20191, US

(21) Appl. No.: 10/372,211

(22) Filed: Feb. 25, 2003

(30) Foreign Application Priority Data
Aug. 23, 2002 (KR) 2002-49978

(51) Int. Cl. H01L 21/306

(52) U.S. Cl. 156/345.43

(57) ABSTRACT

A plasma etching apparatus includes a process chamber, an upper electrode and a lower electrode disposed vertically opposite to each other within the process chamber, an electrostatic chuck disposed on the lower electrode, a focus ring surrounding the electrostatic chuck, and a shield ring covering an outer circumferential part of the upper electrode. The shield ring has a guide part extending vertically downwardly away from the bottom of the upper electrode and terminating proximate an uppermost part of the focus ring, and a plurality of exhaust holes extending radially therethrough. The shield ring prevents polymer from adhering to relatively cool parts thereof, causes the plasma to flow substantially downwardly so as not to etch the shield ring or the focus ring and facilitates the discharge of by-products from the process chamber.

### BACKGROUND OF THE INVENTION

1. Field of the Invention

The present invention relates to the fabricating of semiconductor devices. More particularly, the present invention relates to an etching apparatus for etching a layer on a semiconductor substrate, and to a shield ring for shielding an upper electrode of such an apparatus.

2. Description of the Related Art

In general, an etching apparatus of semiconductor fabricating equipment is used to form a contact hole by etching a dielectric film of a wafer. Such a general etching apparatus is shown in FIG. 1.

The etching apparatus used in fabricating semiconductor devices includes a chamber 1, an upper electrode 2 and a lower electrode 3 vertically spaced from each other inside the chamber 1, and an electrostatic chuck 4 for chucking a wafer using an electrostatic force. The electrostatic chuck 4 is disposed on an upper part of the lower electrode 3. On the other hand, a wafer W is disposed on the electrostatic chuck 4.

Source gas is charged through gas inflow apertures of the upper electrode 2, and RF(Radio Frequency) power is applied to the upper electrode 2 and the lower electrode 3 while the wafer W is disposed on the electrostatic chuck 4. At this time, plasma is generated between the upper electrode 2 and the wafer W, and a layer of the wafer W is etched by the plasma.

Furthermore, a bottom surface and the outer circumferential surface of the upper electrode 2 are covered with a shield ring 5 so as to protect the upper electrode 2 from the plasma. In addition, a focus ring 6 is disposed along the outer circumferential surface of the electrostatic chuck 4 so as to converge the plasma generated between the upper and lower electrodes 2, 3 onto the wafer W.

The shield ring 5 is made of a dielectric material, typically quartz. A principal function of the shield ring 5 is to prevent particles of polymer from adhering to the upper electrode 2.

More specifically, the shield ring 5 is generally annular. A horizontal part of the shield ring 5 covers part of the bottom surface of the upper electrode 2. The horizontal part of the shield ring 5 defines a through-hole whose diameter is larger than that of the wafer W. A vertical part of the shield ring 5 extends vertically upward from an outer end of the horizontal part, so as to cover the outer circumferential surface of the upper electrode 2.

Particles of polymer are unavoidably generated as a result of the etching process. Such polymer is not very adhesive at high temperatures corresponding to that of the plasma itself but is adhesive at lower temperatures which may prevail at the upper part of the chamber 1. Accordingly, as shown in FIG. 2, the polymer adheres to a bottom surface of the shield ring 5, and such polymer is separated from the shield ring 5 by an eddy created inside the chamber 1 when the RF power is turned off. The particles of the polymer that fall from the shield ring 5 stick to the wafer W, and thereby contaminate wafer W.

Still further, ionic components of the plasma generated between the upper electrode 2 and the wafer W have a non-directional distribution as shown in FIG. 3. Consequently, these components of the plasma etch portions of both the shield ring 5 and the focus ring 6. Such an etching of the shield ring 5 and the focus ring 6 causes numerous particles and scrap to accumulate on the wafer W.

### SUMMARY OF THE INVENTION

Therefore, an object of the present invention is to provide an etching apparatus, which is capable of preventing wafers from being contaminated, especially by particles of polymer generated by an etching process.

Another object of the present invention is to provide an etching apparatus, which can produce plasma having a uniform distribution, i.e., a flow in only one direction, thereby enhancing the efficiency of the etching process and prolonging the useful life of the components of the apparatus.

To achieve these objects, the present invention provides a shield ring for the upper electrode of an etching apparatus, having a guide part extending vertically downwardly away from the bottom of the upper electrode. The guide part has a plurality of exhaust holes extending horizontally therethrough such that by-products of an etching process can be exhausted through the exhaust holes

In the etching apparatus, the upper electrode and a lower electrode are disposed vertically opposite to each other inside a process chamber of the apparatus. An electrostatic chuck for fixing a wafer in position in the chamber is disposed is on an upper part of the lower electrode. The focus ring surrounds an outer circumferential surface of the electrostatic chuck. An outer circumferential part of the upper electrode is covered with the shield ring such that its guide part extends vertically, downwardly and terminates proximate an uppermost part of a focus ring. The exhaust holes allow by-products to be exhausted from the process chamber.

### BRIEF DESCRIPTION OF THE DRAWINGS

The above and other objects and features of the present invention will become more apparent from the following detailed description of the preferred embodiments thereof taken in conjunction with the accompanying drawings, in which:

FIG. 1 is a sectional view of a conventional etching apparatus;

FIG. 2 is an enlarged view of part of the conventional etching apparatus, showing particles of polymer generated during an etching process adhered to the shield ring of the apparatus;

FIG. 3 is a similar view but showing the etching of the shield ring and the focus ring by plasma during the etching process;

FIG. 4 is a sectional view of an etching apparatus in accordance with the present invention;

FIG. 5 is a sectional view of a shield ring in accordance with the present invention;

FIG. 6 is a sectional view of the etching apparatus of the present invention illustrating a state in which a wafer is being loaded into the apparatus;

FIG. 7 is a sectional view of the etching apparatus of the present invention illustrating the flow properties of the plasma during an etching process; and

FIG. 8 is a sectional view of the etching apparatus of the present invention illustrating the discharge by-products from the inside of the chamber after an etching process has been performed.

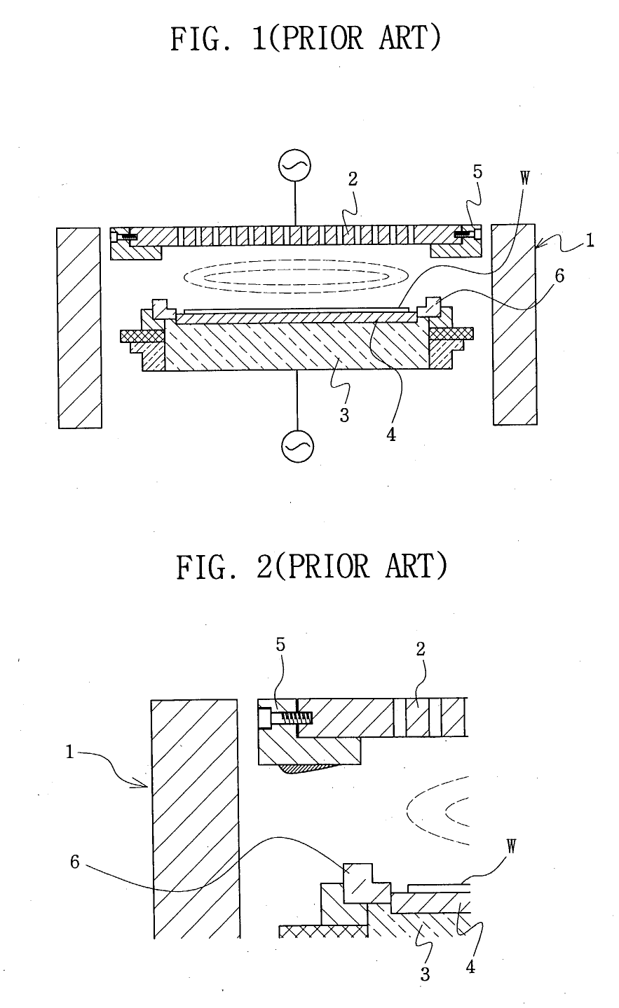

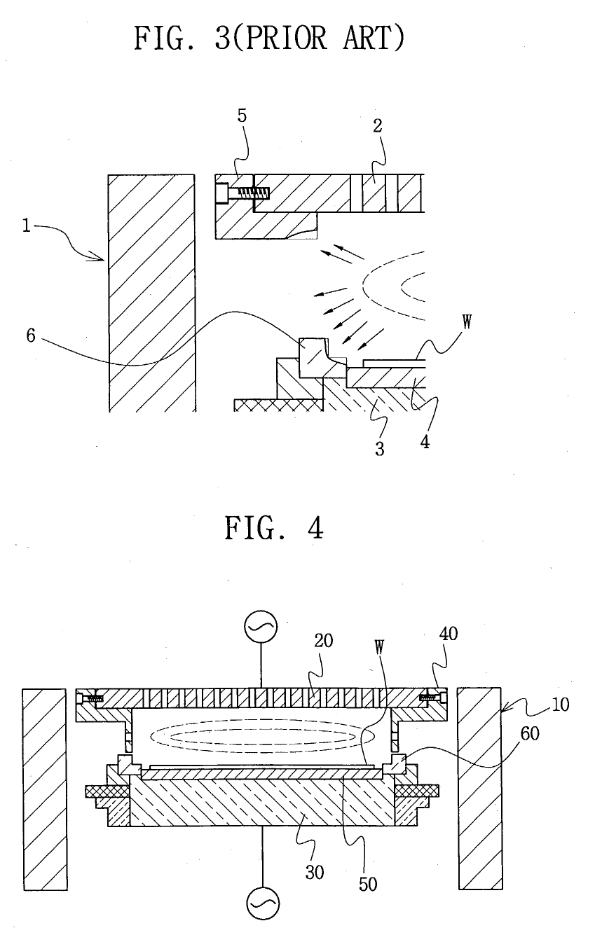

### DETAILED DESCRIPTION OF THE PREFERRED EMBODIMENTS

Hereinafter, preferred embodiments of the present invention will be described in detail with reference to FIGS. 4 through 8.

Referring first to FIG. 4, an upper electrode 20 and a lower electrode 30 confront each other within a chamber 10 as vertically spaced from each other. An outer circumferential part of the upper electrode 20 is covered with a shield ring 40. An electrostatic chuck 50 for supporting a wafer is disposed on an upper part of the lower electrode 30. An outer circumferential surface of the electrostatic chuck 50 is covered with a focus ring 60.

Furthermore, an assembly comprising the lower electrode 30 and the electrostatic chuck 50 fixed thereto is supported so as to be movable upwardly and downwardly in the chamber 10.

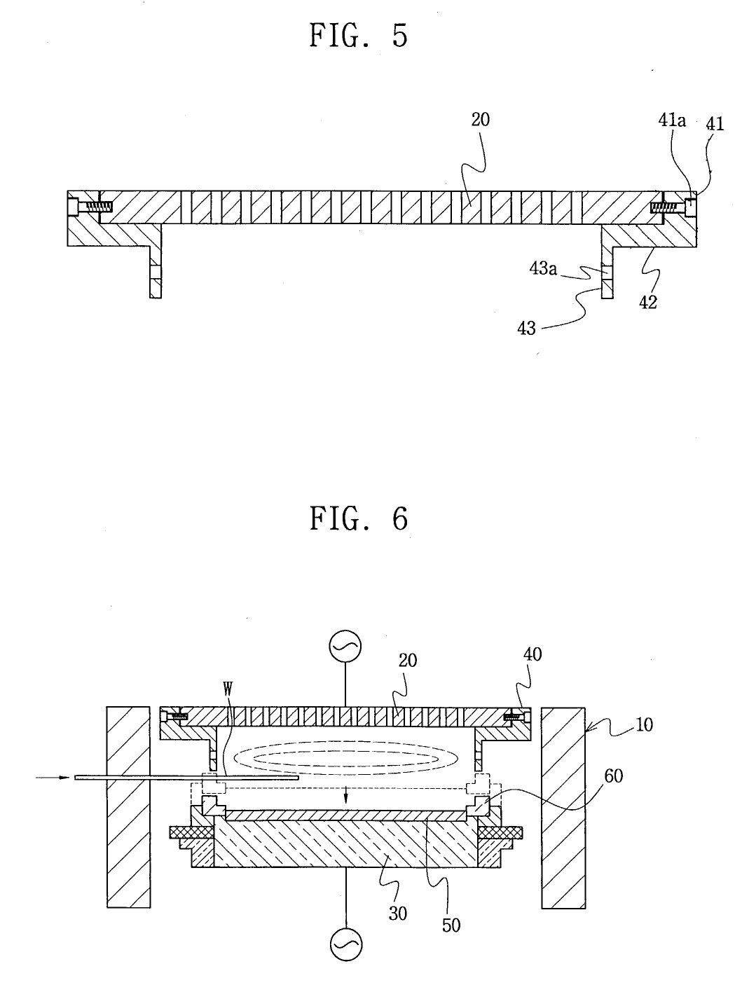

Referring now to FIG. 5, the shield ring 40 is a unitary body made of quartz. The diameter of the shield ring 40 is larger at its top than at than at its bottom, such that the shield ring 40 generally has the shape of a stepped cylinder. More specifically, the shield ring 40 comprises a cylindrical cover part 41, an annular acceptance part 42, and a cylindrical guide part 43.

The cover part 41 surrounds an outer circumferential surface of the upper electrode 20 to which RF power is applied. The cover part 41 is fastened to the upper electrode 20 from the outside by bolts. To this end, a plurality of fastening holes 41a extend radially through the cover part so as to receive the bolts by which the shield ring 40 is fastened to the upper electrode 20.

The acceptance part 42 extends horizontally inwardly from a lower end of the cover part 41. The upper electrode 20 is supported on the acceptance part 42. That is, when the upper electrode 20 is inserted into the shield ring 40, the upper electrode 20 rests on the acceptance part 42 so as to be stably supported.

The guide part 43 is cylindrical and extends vertically downwardly from an inner end of the acceptance part 42. The inner diameter of the guide part 43 is larger than the diameter of the wafer W that is to be mounted on the electrostatic chuck 50. The bottom of the guide part 43 is located approximate an upper part of the focus ring 60 such that only a minute gap is left therebetween.

Furthermore, the guide part 43 has numerous exhaust holes 43a that extend radially therethrough and are spaced from one another in the circumferential direction of the guide part 43. The size and number of the exhaust holes 43a are sufficient to smoothly exhaust a by-product of the etching process immediately after the etching process is over. The exhausting of the by-product through the exhaust holes 43a is facilitated by pumping air from the chamber 10.

The etching apparatus according to the present invention operates as follows.

When the wafer W is loaded inside the chamber 10, the assembly comprising the lower electrode 30 is lowered a given amount so as to form a gap of a predetermined width between the shield ring 40 and the focus ring 60 (FIG. 6). A plurality of lift pins (not shown in the drawings) project from the upper surface electrostatic chuck 50. The wafer W is inserted between the upper electrode 20 and the electrostatic chuck 50 and is set on the lift pins.

Then, the lift pins are lowered such that the wafer W is set on the electrostatic chuck 50. At this time, the assembly comprising the lower electrode 30 is raised to a home position at which the upper part of the focus ring 60 is disposed proximate the lower end of the guide part 43 of the shield ring 40.

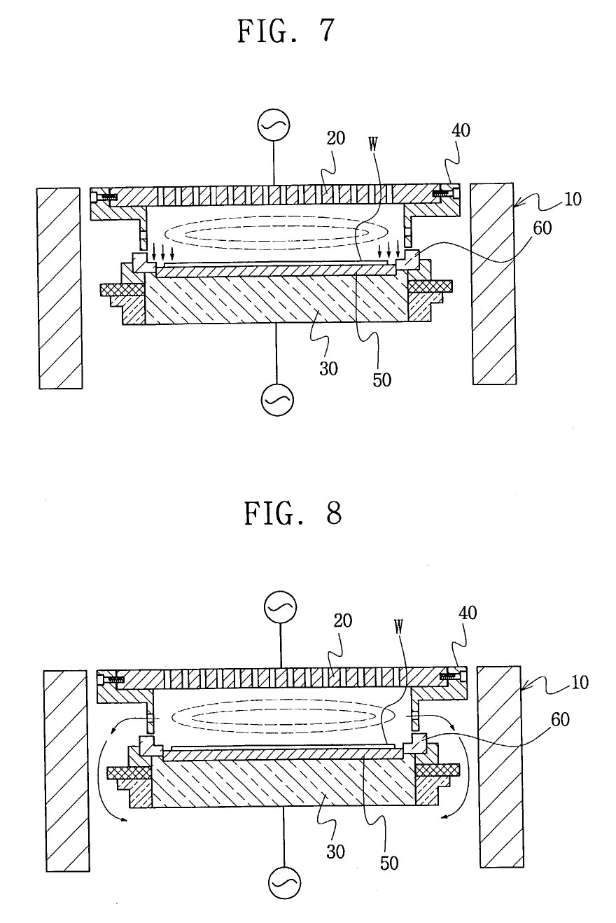

Subsequently, as shown in FIG. 7, the source gas flows into the space delimited by the electrostatic chuck 50, focus ring 60, guide part 43 of the shield ring 40, and upper electrode 20 from a chamber defined above the upper electrode 20. At the same time, RF power is applied to the upper electrode 20 and the lower electrode 30. As a result, plasma is generated between the wafer W and the upper electrode 20. The plasma collides with a dielectric film of the wafer W, for example, to thus etch the film.

The inner circumferential surface of the guide part 43 directly contacts the plasma so as to be exposed to a high temperature. Thus, polymer generated during the etching operation is prevented from adhering to the guide part 43. Also, the guide part 43 of the shield ring 40 extends downward, vertically, to a location proximate the upper end of the focus ring 60 to prevent the polymer from depositing on an outer circumferential surface of the shield ring 40 that has a comparatively lower temperature than the inner circumferential surface.

Also, as shown in FIG. 7, the directionality of the plasma is enhanced by the downwardly extending vertical guide part 43 of the shield ring 40. The components of the plasma are limited to flowing vertically downwardly along the inner circumferential surface of the shield ring 40. Thus, nearly all of the plasma is converged onto the wafer W, whereby the efficiency of the etching process is enhanced.

The high degree of directionality of the plasma, as produced by the guide part 43 of shield ring 40, also prevents the shield ring 40 or the focus ring 60 from being etched. Thus, the present invention prolongs the useful life of these components.

When the RF power is turned off, the by-products inside the chamber 10, including particles of polymer, can be smoothly discharged through the exhaust holes 43a in the guide part 43, by a pumping operation, as shown in FIG. 8. Accordingly, the wafer W can be prevented from being contaminated.

As described above in accordance with the present invention, the shield ring 40 includes a guide part 43 in which exhaust holes 43a are formed, to thereby prevent the wafer from being contaminated by particles of polymer generated during the etching process and to thereby facilitate a vertically downward straight flow of the plasma. Accordingly, the etching process is less prone to failure, the useful life of the components of the apparatus, such as the shield ring 40 and the focus ring 60, can be prolonged together, cost-savings can be realized in connection with the required maintenance of the apparatus.

Finally, although the present invention was described in detail above in connection with the preferred embodiments thereof, the scope of the invention is not so limited. Rather, various changes and modifications of the preferred embodiments, as will become apparent to those of ordinary skill in the art, are seen to be within the true spirit and scope of the invention as defined by the appended claims.

What is claimed is:

1. A plasma etching apparatus comprising: a process chamber; an upper electrode and a lower electrode disposed opposite to each other within said process chamber as spaced vertically from each other; an electrostatic chuck disposed on an upper part of said lower electrode; a focus ring surrounding an outer circumferential surface of said electrostatic chuck; and a shield ring covering an outer circumferential part of said upper electrode, said shield ring having a guide part extending vertically downwardly away from the bottom of said upper electrode and terminating proximate an uppermost part of said focus ring, said guide part having a plurality of exhaust holes extending horizontally therethrough and open to said process chamber such that by-products of an etching process carried out in the chamber can be exhausted through said exhaust holes.

2. The apparatus of claim 1, wherein said shield ring also has a cover part that covers an outer circumferential surface of said upper electrode, and an acceptance part on which said upper electrode is supported, said guide part extending vertically downwardly from a radially inner end of said acceptance part.

3. The apparatus of claim 2, wherein said electrostatic chuck is configured to support a wafer of a certain diameter, and the inner diameter of said guide part is larger than the diameter of a wafer that can be supported by said electrostatic chuck.

4. The apparatus of claim 2, wherein said exhaust holes are spaced from one another in the circumferential direction of the guide part of said shield ring.

5. The apparatus of claim 1, wherein said shield ring is made of quartz.

6. A shield ring for use in a plasma etching apparatus having an upper electrode and a lower electrode disposed opposite to each other within a process chamber, said shield ring comprising: a cylindrical cover part sized to cover an outer circumferential surface of the upper electrode, an annular acceptance part extending radially inwardly from a lower end of said cover part for use in covering a portion of a bottom surface of the upper electrode, and a cylindrical guide part extending vertically downwardly from a radially inner end of said acceptance part, said cylindrical guide part having a plurality of exhaust holes extending radially therethrough.

7. The shield ring of claim 6, wherein said exhaust holes are spaced from one another in the circumferential direction of said cylindrical guide part.

8. The shield ring of claim 6, wherein said cover part, said acceptance part and said guide part are unitary and of quartz.
